(19) United States
(12) Patent Application Publication
(10) Pub. No.: US 2012/0231292 A1
(43) Pub. Date: Sep. 13, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); NAN MA, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/178,653

(22) Filed: Jul. 8, 2011

(30) Foreign Application Priority Data
Mar. 11, 2011 (CN) 201110058261.5

(51) Int. Cl. B32B 15/04; B32B 5/00; C23C 14/35; B32B 7/02

(52) U.S. Cl. 428/623; 428/469; 428/216; 428/336; 204/192.15

(57) ABSTRACT

A coated article is described. The coated article includes an aluminum or aluminum alloy substrate, a combined gradient layer formed on the substrate, and a decorative layer formed on the combined gradient layer. The combined gradient layer includes a plurality of aluminum-oxygen-nitrogen layers. The atomic percentage of aluminum atoms within the combined gradient layer is gradually decreased from near the substrate to far away the substrate, the atomic percentages of oxygen atoms and nitrogen atoms within the combined gradient layer are gradually increased from near the substrate to far away the substrate. The decorative layer is a non-metallic layer. A method for making the coated article is also described.

### BACKGROUND

1. Technical Field

The present disclosure relates to a coated article and a method for making the coated article.

2. Description of Related Art

Aluminum or aluminum alloy is widely used for its excellent properties. To protect or decorate the aluminum or aluminum alloy, protective or decorative layers may be formed on the aluminum or aluminum alloy by anodizing, painting, or vacuum depositing. However, the anodizing and painting processes are not environmentally friendly, and the layers formed by vacuum depositing are poorly bonded to the aluminum or aluminum alloy. This is because the aluminum or aluminum alloy has a high coefficient of thermal expansion compared to most of the non-metallic ingredients that may be vacuum deposited on the aluminum or aluminum alloy to form the protective or decorative layers.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of a coated article.

FIG. 2 is an overlook view of an exemplary embodiment of a vacuum sputtering device.

### DETAILED DESCRIPTION

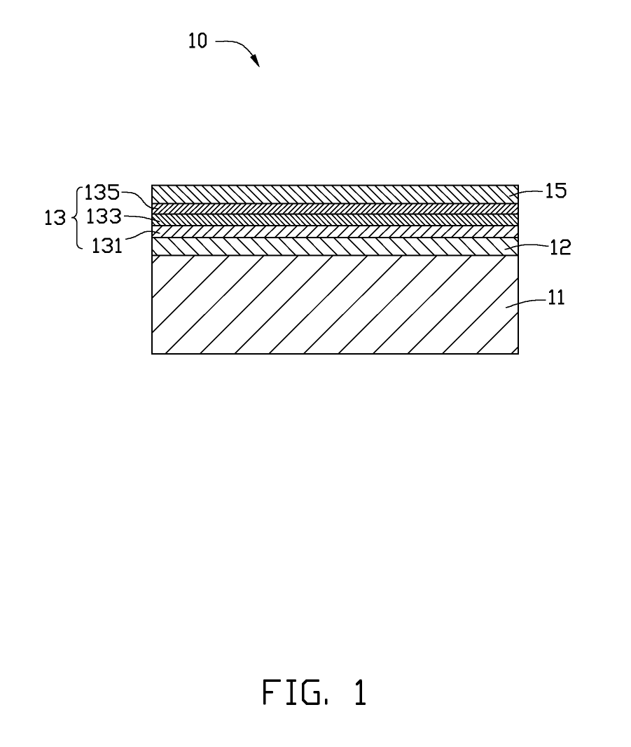

FIG. 1 shows a coated article 10 according to an exemplary embodiment. The coated article 10 includes an aluminum or aluminum alloy substrate 11, an aluminum layer 12 formed on a surface of the substrate 11, a combined gradient layer 13 formed on the aluminum layer 12, and a decorative layer 15 formed on the combined gradient layer 13.

The aluminum layer 12 may be formed by vacuum sputtering. The aluminum layer 12 may have a thickness of about 120 nm-200 nm. The aluminum layer 12 enhances the bond of the layers of the coated article 10 to the substrate 11.

The combined gradient layer 13 may be formed by vacuum sputtering. The combined gradient layer 13 includes a plurality of aluminum-oxygen-nitrogen (AlON) layers in which the atomic percentages of the aluminum atoms, oxygen atoms, and nitrogen atoms are gradually changed.

In the exemplary embodiment, the AlON layers includes a first AlON layer 131, a second AlON layer 133, and a third AlON layer 135 formed on the aluminum layer 12 in that order. The first AlON layer 131, second AlON layer 133, and third AlON layer 135 may all have a thickness of about 130 nm-160 nm. In the first AlON layer 131, the aluminum has an atomic percentage of about 65%-75%, the oxygen has an atomic percentage of about 10%-20%, and the nitrogen has an atomic percentage of about 10%-20%. In the second AlON layer 133, the aluminum has an atomic percentage of about 50%-60%, the oxygen has an atomic percentage of about 20%-30%, and the nitrogen has an atomic percentage of about 15%-25%. In the third AlON layer 135, the aluminum has an atomic percentage of about 42%-52%, the oxygen has an atomic percentage of about 23%-33%, and the nitrogen has an atomic percentage of about 20%-30%.

The atomic percentage of the aluminum atoms within the combined gradient layer 13 is gradually decreased from the bottom of the combined gradient layer 13 near the aluminum layer 12 (or the substrate 11) to the top of the combined gradient layer 13 away from the aluminum layer 12 (or the substrate 11). The atomic percentages of the oxygen atoms and nitrogen atoms within the combined gradient layer 13 are gradually increased from near the aluminum layer 12 (or the substrate 11) to far away the aluminum layer 12 (or the substrate 11). As such, the coefficients of thermal expansion of the combined gradient layer 13 is gradually decreased from the first AlON layer 131 to the third AlON layer 135, such coefficient change of thermal expansion reduces the coefficient difference between each two adjacent layers, which improves the bond among each of the layers of the coated article 10 and the substrate 11.

Additionally, the third AlON layer 135 has a high density, which further provides the coated article 10 a good corrosion resistance property.

The decorative layer 15 may be a non-metallic layer formed on the third AlON layer 135 by vacuum sputtering. The non-metallic layer may be a layer of titanium nitride (TiN), titanium-nitrogen-oxygen (TiNO), titanium-carbon-nitrogen (TiCN), chromium nitride (CrN), chromium-nitrogen-oxygen (CrNO), or chromium-carbon-nitrogen (CrCN). The coefficient of thermal expansion of the decorative layer 15 is close to the third AlON layer 135, so the decorative layer 15 is tightly bonded to the third AlON layer 135. The decorative layer 15 may have a thickness of about 150 nm-300 nm.

It is to be understood that the aluminum layer 12 may be omitted, and the combined gradient layer 13 can be directly formed on the substrate 11.

It is to be understood that the combined gradient layer 13 may only include two AlON layers, or may include more than three AlON layers.

A method for making the coated article 10 may include the following steps:

The substrate 11 is pre-treated. The pre-treating process may include the following steps:

The substrate 11 is cleaned in an ultrasonic cleaning device (not shown) filled with ethanol or acetone.

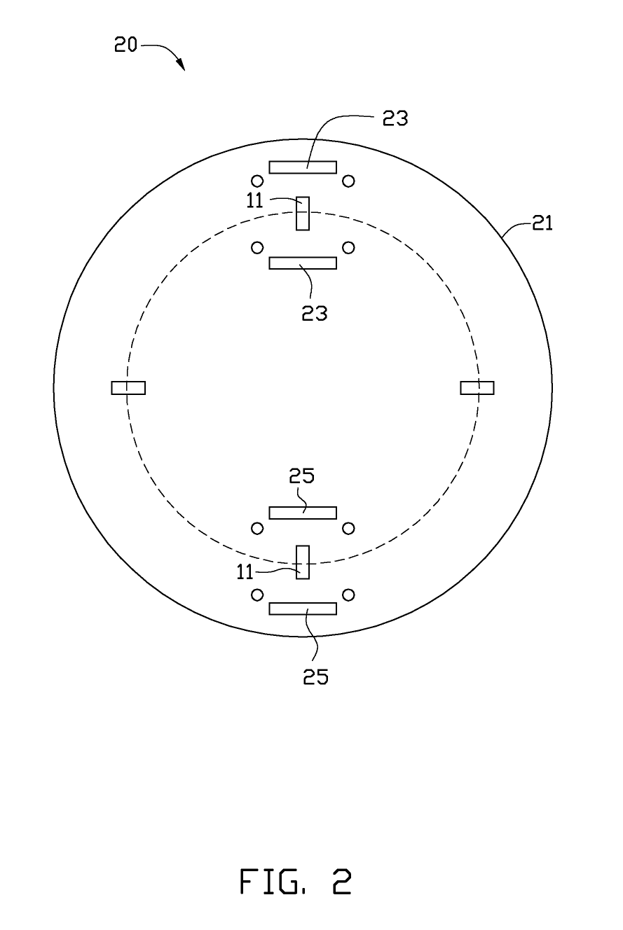

The substrate 11 is plasma cleaned. Referring to FIG. 2, the substrate 11 may be positioned in a coating chamber 21 of a vacuum sputtering device 20. Aluminum targets 23 and titanium targets 25 are fixed in the coating chamber 21. The coating chamber 21 is then evacuated to about 8.0×10⁻³ Pa. Argon gas having a purity of about 99.999% may be used as a working gas and is injected into the coating chamber 21 at a flow rate of about 150 standard-state cubic centimeters per minute (sccm) to 300 sccm. The substrate 11 may have a negative bias voltage of about −300 V to about −500 V, then high-frequency voltage is produced in the coating chamber 21 and the argon gas is ionized to plasma. The plasma then strikes the surface of the substrate 11 to clean the surface of the substrate 11. Plasma cleaning of the substrate 11 may take about 5 minutes (min) to 10 min. The plasma cleaning process enhances the bond between the substrate 11 and the layers of the coated article 10. The aluminum targets 23 and titanium targets 25 are unaffected by the pre-cleaning process.

The aluminum layer 12 may be magnetron sputtered on the pretreated substrate 11 by using a power at an intermediate frequency for the aluminum targets 23. Magnetron sputtering of the aluminum layer 12 is implemented in the coating chamber 21. The internal temperature of the coating chamber 21 may be of about 20° C.-200° C. Argon gas may be used as a working gas and is injected into the coating chamber 21 at a flow rate of about 150 sccm-250 sccm. The power at an intermediate frequency is then applied to the aluminum targets 23, and aluminum atoms are sputtered off from the aluminum targets 23 and deposited on the substrate 11 to form the aluminum layer 12. During the depositing process, the substrate 11 may have a negative bias voltage of about −50 V to about −250 V. Depositing of the aluminum layer 12 may take about 20 min-40 min.

The first AlON layer 131 may be magnetron sputtered on the aluminum layer 12 by using a power at an intermediate frequency for the aluminum targets 23. Magnetron sputtering of the first AlON layer 131 is implemented in the coating chamber 21. The internal temperature of the coating chamber 21 may be of about 20° C.-120° C. Nitrogen (N₂) and oxygen (O₂) may be used as reaction gases and are injected into the coating chamber 21 all at a flow rate of about 15 sccm-25 sccm, and argon gas may be used as a working gas and is injected into the coating chamber 21 at a flow rate of about 150 sccm-250 sccm. Then aluminum atoms sputtered off from the aluminum targets 23, oxygen atoms, and nitrogen atoms are ionized in an electrical field in the coating chamber 21. The ionized aluminum then chemically reacts with the ionized nitrogen and oxygen to deposit the first AlON layer 131 on the aluminum layer 12. During the deposition process, the substrate 11 may have a negative bias voltage of about −50 V to about −250 V. Depositing of the first AlON layer 131 may take about 30 min-40 min

The second AlON layer 133 may be magnetron sputtered on the first AlON layer 131. The process of magnetron sputtering the second AlON layer 133 is similar to that of the first AlON layer 131. The only difference is the flow rates of nitrogen and oxygen for the second AlON layer 133 are all about 35 sccm-45 sccm.

The third AlON layer 135 may be magnetron sputtered on the second AlON layer 133. The process of magnetron sputtering the third AlON layer 135 is similar to that of the first AlON layer 131. The only difference is the flow rates of nitrogen and oxygen for the third AlON layer 133 are all about 55 sccm-65 sccm.

The decorative layer 15 may be magnetron sputtering on the third AlON layer 135. In this embodiment, a titanium nitride (TiN) layer may be sputtered to illustrate the formation of the decorative layer 15. Magnetron sputtering of the TiN layer is implemented in the coating chamber 21 by using a power at an intermediate frequency for the titanium targets 25. The internal temperature of the coating chamber 21 may be of about 20° C.-120° C. Nitrogen (N₂) may be used as a reaction gas and is injected into the coating chamber 21 at a flow rate of about 30 sccm-50 sccm, and argon gas may be used as a working gas and is injected into the coating chamber 21 at a flow rate of about 150 sccm-250 sccm. Then titanium atoms sputtered off from the titanium targets 25 and nitrogen atoms are ionized in an electrical field in the coating chamber 21. The ionized titanium then chemically reacts with the ionized nitrogen to deposit the TiN layer on the third AlON layer 135, to form the decorative layer 15. During the deposition process, the substrate 11 may have a negative bias voltage of about −150 V to about −200 V. Depositing of the TiN layer may take about 20 min-40 min. The titanium contained in the TiN may have an atomic percentage of about 55%-65%, and the nitrogen contained in the TiN may have an atomic percentage of about 35%-45%.

Specific examples of making the coated article 10 are described as following. The ultrasonic cleaning in these specific examples may be substantially the same as described above so it is not described here again. Additionally, the process of magnetron sputtering the layers 12, 13, and 15 in the specific examples is substantially the same as described above, and the specific examples mainly emphasize the different process parameters of making the coated article 10.

### EXAMPLE 1

Plasma cleaning the substrate 11: the flow rate of Ar is 280 sccm; the substrate 11 has a negative bias voltage of −300 V; plasma cleaning of the substrate 11 takes 9 min.

Sputtering to form aluminum layer 12 on the substrate 11: the flow rate of Ar is 150 sccm; the substrate 11 has a negative bias voltage of −200 V; the internal temperature of the coating chamber 21 is 30° C.; sputtering of the aluminum layer 12 takes 20 min; the aluminum layer 12 has a thickness of 120 nm.

Sputtering to form first AlON layer 131 on the aluminum layer 12: the flow rate of Ar is 150 sccm, the flow rate of N₂ is 20 sccm, the flow rate of O₂ is 20 sccm; the substrate 11 has a negative bias voltage of −200 V; the internal temperature of the coating chamber 21 is 30° C.; sputtering of the first AlON layer 131 takes 30 min; the first AlON layer 131 has a thickness of 130 nm; the aluminum within the first AlON layer 131 has an atomic percentage of about 70%, the oxygen within the first AlON layer 131 has an atomic percentage of about 15%, the nitrogen within the first AlON layer 131 has an atomic percentage of about 15%.

Sputtering to form second AlON layer 133 on the first AlON layer 13: the flow rate of Ar is 150 sccm, the flow rate of N₂ is 40 sccm, the flow rate of O₂ is 40 sccm; the substrate 11 has a negative bias voltage of −200 V; the internal temperature of the coating chamber 21 is 30° C.; sputtering of the second AlON layer 133 takes 35 min; the second AlON layer 133 has a thickness of 150 nm; the aluminum within the second AlON layer 133 has an atomic percentage of about 55%, the oxygen within the second AlON layer 133 has an atomic percentage of about 25%, the nitrogen within the second AlON layer 133 has an atomic percentage of about 20%.

Sputtering to form third AlON layer 135 on the second AlON layer 135: the flow rate of Ar is 150 sccm, the flow rate of N₂ is 60 sccm, the flow rate of O₂ is 60 sccm; the substrate 11 has a negative bias voltage of −200 V; the internal temperature of the coating chamber 21 is 30° C.; sputtering of the first AlON layer 131 takes 40 min; the third AlON layer 135 has a thickness of 160 nm; the aluminum within the third AlON layer 135 has an atomic percentage of about 47%, the oxygen within the third AlON layer 135 has an atomic percentage of about 28%, the nitrogen within the third AlON layer 135 has an atomic percentage of about 25%.

Sputtering TiN on the third AlON layer 135 to form decorative layer 15: the flow rate of Ar is 150 sccm, the flow rate of N₂ is 40 sccm; the substrate 11 has a negative bias voltage of −180 V; the internal temperature of the coating chamber 21 is 30° C.; sputtering of the TiN takes 30 min; the TiN layer has a thickness of 200 nm; the titanium within the TiN has an atomic percentage of about 60%, and the nitrogen within the TiN has an atomic percentage of about 40%.

### EXAMPLE 2

Plasma cleaning the substrate 11: the flow rate of Ar is 280 sccm; the substrate 11 has a negative bias voltage of −300 V; plasma cleaning of the substrate 11 takes 7 min.

Sputtering to form aluminum layer 12 on the substrate 11: the flow rate of Ar is 200 sccm; the substrate 11 has a negative bias voltage of −200 V; the internal temperature of the coating chamber 21 is 50° C.; sputtering of the aluminum layer 12 takes 30 min; the aluminum layer 12 has a thickness of 180 nm.

Sputtering to form first AlON layer 131 on the aluminum layer 12: the flow rate of Ar is 200 sccm, the flow rate of N₂ is 25 sccm, the flow rate of O₂ is 25 sccm; the substrate 11 has a negative bias voltage of −100 V; the internal temperature of the coating chamber 21 is 50° C.; sputtering of the first AlON layer 131 takes 40 min; the first AlON layer 131 has a thickness of 150 nm; the aluminum within the first AlON layer 131 has an atomic percentage of about 65%, the oxygen within the first AlON layer 131 has an atomic percentage of about 18%, the nitrogen within the first AlON layer 131 has an atomic percentage of about 17%.

Sputtering to form second AlON layer 133 on the first AlON layer 13: the flow rate of Ar is 200 sccm, the flow rate of N₂ is 45 sccm, the flow rate of O₂ is 45 sccm; the substrate 11 has a negative bias voltage of −100 V; the internal temperature of the coating chamber 21 is 50° C.; sputtering of the second AlON layer 133 takes 40 min; the second AlON layer 133 has a thickness of 160 nm; the aluminum within the second AlON layer 133 has an atomic percentage of about 50%, the oxygen within the second AlON layer 133 has an atomic percentage of about 27%, the nitrogen within the second AlON layer 133 has an atomic percentage of about 23%.

Sputtering to form third AlON layer 135 on the second AlON layer 135: the flow rate of Ar is 200 sccm, the flow rate of N₂ is 65 sccm, the flow rate of O₂ is 65 sccm; the substrate 11 has a negative bias voltage of −100 V; the internal temperature of the coating chamber 21 is 50° C.; sputtering of the first AlON layer 131 takes 40 min; the third AlON layer 135 has a thickness of 160 nm; the aluminum within the third AlON layer 135 has an atomic percentage of about 42%, the oxygen within the third AlON layer 135 has an atomic percentage of about 30%, the nitrogen within the third AlON layer 135 has an atomic percentage of about 28%.

Sputtering TiN on the third AlON layer 135 to form decorative layer 15: the flow rate of Ar is 150 sccm, the flow rate of N₂ is 40 sccm; the substrate 11 has a negative bias voltage of −180 V; the internal temperature of the coating chamber 21 is 50° C.; sputtering of the TiN takes 30 min; the TiN layer has a thickness of 210 nm; the titanium within the TiN has an atomic percentage of about 60%, and the nitrogen within the TiN has an atomic percentage of about 40%.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
an aluminum or aluminum alloy substrate;
a combined gradient layer formed on the substrate, the combined gradient layer comprising a plurality of aluminum-oxygen-nitrogen layers, the atomic percentage of aluminum atoms within the combined gradient layer being gradually decreased from near the substrate to far away the substrate, the atomic percentages of oxygen atoms and nitrogen atoms within the combined gradient layer being gradually increased from near the substrate to far away the substrate; and
a decorative layer formed on the combined gradient layer, the decorative layer being a non-metallic layer.

2. The coated article as claimed in claim 1, wherein the combined gradient layer comprising a first aluminum-oxygen-nitrogen layer, a second aluminum-oxygen-nitrogen layer, and a third aluminum-oxygen-nitrogen layer formed on the substrate in that order.

3. The coated article as claimed in claim 2, wherein aluminum, oxygen, and nitrogen contained in the first aluminum-oxygen-nitrogen layer have an atomic percentage of about 65%-75%, 10%-20%, and 10%-20% respectively; aluminum, oxygen, and nitrogen contained in the second aluminum-oxygen-nitrogen layer have an atomic percentage of about 50%-60%, 20%-30%, and 15%-25% respectively; and aluminum, oxygen, and nitrogen contained in the third aluminum-oxygen-nitrogen layer have an atomic percentage of about 42%-52%, 23%-33%, and 20%-30% respectively.

4. The coated article as claimed in claim 2, wherein the first, second, and third aluminum-oxygen-nitrogen layer all have a thickness of about 130 nm-160 nm.

5. The coated article as claimed in claim 1, further comprising an aluminum layer formed between the substrate and the combined gradient layer.

6. The coated article as claimed in claim 5, wherein the aluminum layer has a thickness of about 120 nm-200 nm.

7. The coated article as claimed in claim 1, wherein the decorative layer is a layer of titanium nitride, titanium-oxygen-nitrogen, titanium-carbon-nitrogen, chromium nitride, chromium-oxygen-nitrogen, or chromium-carbon-nitrogen; the decorative layer has a thickness of about 150 nm-300 nm.

8. The coated article as claimed in claim 5, wherein the aluminum layer, the combined gradient layer, and the decorative layer are all formed by vacuum sputtering.

9. A method for making a coated article, comprising:
providing an aluminum or aluminum alloy substrate;
forming a combined gradient layer on the substrate by vacuum sputtering, using nitrogen and oxygen as reaction gases and using aluminum target; the combined gradient layer comprising a plurality of aluminum-oxygen-nitrogen layers, the atomic percentage of aluminum atoms within the combined gradient layer being gradually decreased from near the substrate to far away the substrate, the atomic percentages of oxygen atoms and nitrogen atoms within the combined gradient layer being gradually increased from near the substrate to far away the substrate; and
forming a decorative layer on the combined gradient layer by vacuum sputtering, the decorative layer being a non-metallic layer.

10. The method as claimed in claim 9, wherein forming the combined gradient layer comprising the steps of forming a first aluminum-oxygen-nitrogen layer, a second aluminum-oxygen-nitrogen layer, and a third aluminum-oxygen-nitrogen layer on the substrate in order.

11. The method as claimed in claim 10, wherein forming the first aluminum-oxygen-nitrogen layer is by using a magnetron sputtering process, the nitrogen has a flow rate of about 15 sccm-25 sccm, the oxygen has a flow rate of about 15 sccm-25 sccm; magnetron sputtering of the first aluminum-oxygen-nitrogen layer uses argon as a working gas, the argon has a flow rate of about 150 sccm-250 sccm; magnetron sputtering of the first aluminum-oxygen-nitrogen layer is conducted at a temperature of about 20° C.-200° C. and takes about 30 min-40 min.

12. The method as claimed in claim 11, wherein the substrate has a negative bias voltage of about −50V to about −250V during sputtering of the first aluminum-oxygen-nitrogen layer.

13. The method as claimed in claim 10, wherein forming the second aluminum-oxygen-nitrogen layer is by using a magnetron sputtering process, the nitrogen has a flow rate of about 35 sccm-45 sccm, the oxygen has a flow rate of about 35 sccm-45 sccm; magnetron sputtering of the second aluminum-oxygen-nitrogen layer uses argon as a working gas, the argon has a flow rate of about 150 sccm-250 sccm; magnetron sputtering of the second aluminum-oxygen-nitrogen layer is conducted at a temperature of about 20° C.-200° C. and takes about 30 min-40 min.

14. The method as claimed in claim 13, wherein the substrate has a negative bias voltage of about −50V to about −250V during sputtering of the second aluminum-oxygen-nitrogen layer.

15. The method as claimed in claim 10, wherein forming the third aluminum-oxygen-nitrogen layer is by using a magnetron sputtering process, the nitrogen has a flow rate of about 55 sccm-65 sccm, the oxygen has a flow rate of about 55 sccm-65 sccm; magnetron sputtering of the third aluminum-oxygen-nitrogen layer uses argon as a working gas, the argon has a flow rate of about 150 sccm-250 sccm; magnetron sputtering of the third aluminum-oxygen-nitrogen layer is conducted at a temperature of about 20° C.-200° C. and takes about 30 min-40 min.

16. The method as claimed in claim 15, wherein the substrate has a negative bias voltage of about −50V to about −250V during sputtering of the third aluminum-oxygen-nitrogen layer.

17. The method as claimed in claim 9, wherein forming the decorative layer comprising the step of forming a layer of titanium nitride, titanium-oxygen-nitrogen, titanium-carbon-nitrogen, chromium nitride, chromium-oxygen-nitrogen, or chromium-carbon-nitrogen.

18. The method as claimed in claim 9, further comprising a step of forming an aluminum layer on the substrate before forming the combined gradient layer.

19. The method as claimed in claim 18, further comprising a step of pre-treating the substrate before forming the aluminum layer.

20. The method as claimed in claim 19, wherein the pre-treating process comprising ultrasonic cleaning the substrate and plasma cleaning the substrate.
